(19) United States
(12) Patent Application Publication
(10) Pub. No.: US 2017/0053883 A1
(43) Pub. Date: Feb. 23, 2017

(54) INTEGRATED CIRCUIT PACKAGE

(71) Applicant: TEXAS INSTRUMENTS INCORPORATED, Dallas, TX (US)

(72) Inventors: You Chye How, Melaka (MY); Huay Yann Tay, Bukit Baru (MY)

(21) Appl. No.: 15/254,948

(22) Filed: Sep. 1, 2016

Related U.S. Application Data
(63) Continuation of application No. 14/215,605, filed on Mar. 17, 2014.

(51) Int. Cl. H01L 23/00; H01L 23/495; H01L 21/48; H01L 23/31

(52) U.S. Cl. CPC H01L 24/13; H01L 24/05; H01L 23/3114; H01L 23/49513; H01L 24/16; H01L 23/49541; H01L 21/4825; H01L 24/11; H01L 24/81; H01L 23/49537; H01L 2224/0401; H01L 2224/02205; H01L 2224/13026; H01L 2224/13078; H01L 2224/13147; H01L 2224/13562; H01L 2224/13647; H01L 2224/13616; H01L 2224/16503; H01L 2224/16245; H01L 2224/1145; H01L 2224/11622; H01L 2224/11618; H01L 2224/1146; H01L 2224/1181; H01L 2224/11614; H01L 2224/8181; H01L 2224/81815; H01L 2924/01327; H01L 2924/3841

(57) ABSTRACT

An integrated circuit (“IC”) package including at least one IC die having a first side with at least two adjacent bump pads thereon and a second side opposite the first side; a first substrate having a first side with a plurality of electrical contact surfaces thereon; and a plurality of copper pillars, each having a first end attached to one of the adjacent bump pads and a second end attached to one of the electrical contact surfaces.

This application is a continuation of U.S. patent application Ser. No. 14/215,605, filed on Mar. 17, 2014, entitled INTEGRATED CIRCUIT PACKAGE which is hereby incorporated by reference for all that it discloses.

### BACKGROUND

There are many types of integrated circuit (IC) packages. One such IC package is disclosed in U.S. Pat. No. 8,304,887, which is hereby incorporated by reference for all that discloses. In that patent an integrated circuit package includes one or more IC dies that are sandwiched between a substrate and a leadframe. The active face of the IC die is electrically and physically attached to the substrate. The backside of the die is mounted on a die attach pad of the leadframe. Other electronic components such as inductors, capacitors, resistors, ferromagnetic materials, etc., are attached to the substrate on the side opposite where the die is attached. Molding compound encapsulates at least portions of the substrate, leadframe, IC die and other electronic components.

### BRIEF DESCRIPTION OF THE DRAWINGS

FIG. 1 is a cross-sectional side elevation view of a prior art IC package, prior to reflow of solder balls on the active face of the die.

FIG. 2 is a cross-sectional side elevation view of the prior art IC package of FIG. 1, after solder ball reflow.

FIG. 3 is a schematic, cross-sectional, elevation view of a bump portion of an IC die.

FIG. 4 is generally the same view as FIG. 3, but after application of a seed layer of Titanium/Copper thereto.

FIG. 5 is generally the same view as FIG. 4, but after application of a photoresist layer over the seed layer.

FIG. 6 is generally the same view as FIG. 5, but after application of UV light to the photoresist layer through a mask/reticle.

FIG. 7 is generally the same view as FIG. 6, but after development of the photoresist layer.

FIG. 8 is generally the same view as FIG. 7, but after copper plating of void regions in the photoresist layer.

FIG. 9 is generally the same view as FIG. 8, but after removal of the remainder of the photoresist layer.

FIG. 10 is generally the same view as FIG. 9, but after etching away of the seed layer from around the copper pillars.

FIG. 11 is a schematic illustration of two sets of copper pillars formed on adjacent bump pads of a silicon die.

FIG. 12 is a schematic top view of one of the sets of copper pillars of FIG. 11 showing the spacing between pillars.

FIG. 13 is a partially cut away top view of a set of copper pillars, similar to FIG. 12, except in an embodiment with more and differently arranged pillars, and showing intermetallic compound filling a portion of the space between copper pillars and showing the ends of the pillars that are remote from the die embedded in a layer of solder.

FIG. 14 is a cross-sectional elevation view of an integrated circuit package, having an IC die sandwiched between two leadframes.

FIG. 15 is a flow chart illustrating a method of making an integrated circuit (“IC”) package.

FIG. 16 is a flow chart illustrating a method of forming a plurality of copper pillars on bump pads of an IC wafer.

### DETAILED DESCRIPTION

This specification, in general, discloses an integrated circuit (“IC”) package 100, FIG. 14. The IC package 100 comprises at least one IC die 110 having a first (active) side 111 with at least two adjacent bump pads 114, 115 thereon and a second (back) side 113 opposite the first side 111. A first substrate, such as a leadframe 160, has a first side 161 with a plurality of electrical contact surfaces 163, 165, etc., thereon. A plurality of spaced apart copper pillars 142 each have a first end 141 attached to one of the adjacent bump pads 114, 115 and a second end 143 attached to one of the electrical contact surfaces, 163, 165. Gaps 144 between pillars 142 are filled, at least partially, with intermetallic compound 146. Having thus described an integrated circuit package 100 in general, structural details thereof and a method of making such integrated circuit packages will now be described.

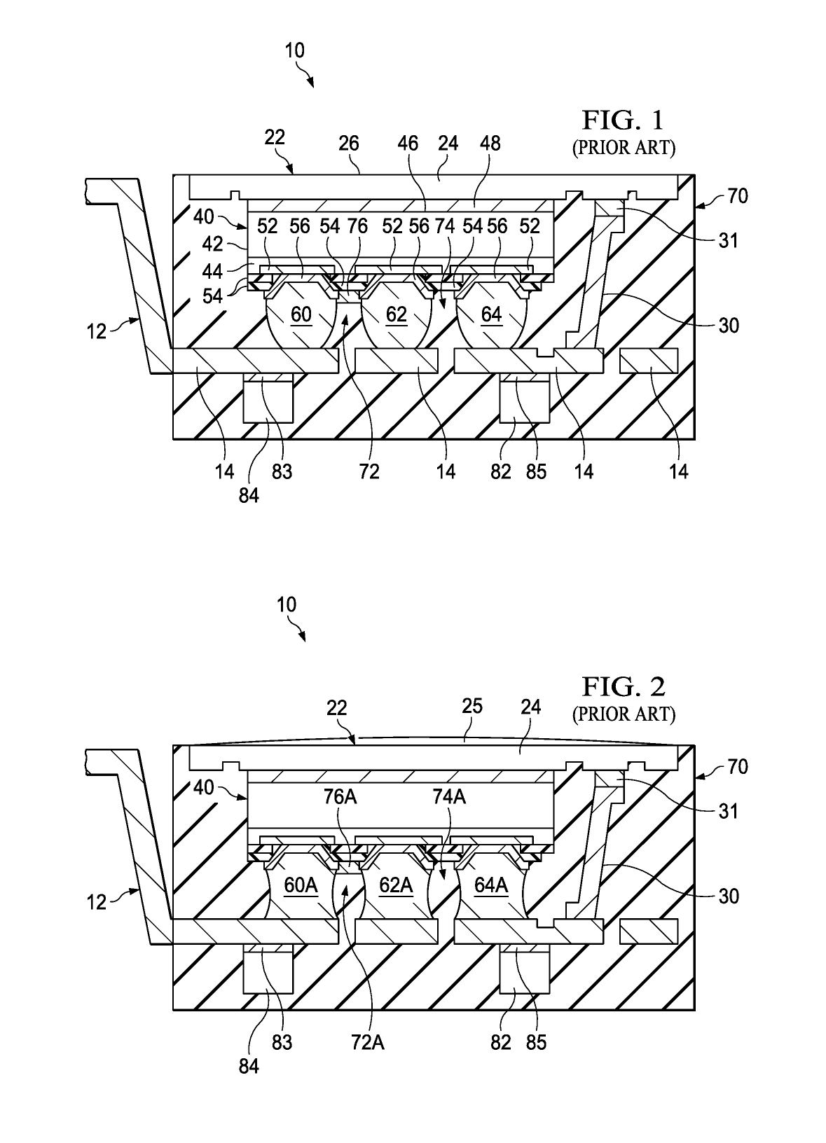

FIG. 1 illustrates a prior art integrated circuit (IC) package 10. The integrated circuit package 10 includes a first (lower) substrate, which may be a first leadframe 12 having a plurality of spaced apart leads or contacts 14. The integrated circuit package 10 includes a second (upper) substrate, which may be a second leadframe 22 with a die attach pad 24. The first and second leadframes 12, 22 may be electrically connected by a lead 30 of the first leadframe 12, which is attached to the second leadframe 22 by a solder layer 31. An integrated circuit die 40 is sandwiched between the first and second leadframes 12, 22. The manner in which the IC package 10 is assembled and various structural details thereof will now be described.

Integrated circuit die 40 includes a silicon block 42 having an active side 44 and a backside 46. Integrated circuit die 40 has a plurality of metal bump pads 52. Each bump pad 52 is circumscribed by a passivation layer 54, which may constitute a double layer as shown in FIG. 1. An under bump metallization layer 56 covers each bump pad 52 and passivation layer 54.

A solder ball 60, 62, 64 is attached to each under bump metallization layer 56 of the die 40. Die 40 with solder balls 60, 62, 64 is flux dipped (not shown) and attached to leadframe 12 leads/contacts 14. The assembly is then heated in a first reflow process that ensures the solder balls are bonded to to the first leadframe 12 leads/contacts 14.

Next the second leadframe 22 is positioned in an inverted position with respect to the orientation shown in FIG. 1. Solder paste 31, 48 is applied to portions of the second leadframe 22 at the locations shown in FIG. 1. The first leadframe 12 with the attached die 40 is then flipped over and the backside 46 of the die 40 is attached to the leadframe 22 by a solder layer 48, which is in the form of solder paste. At the same time interconnect 30 is attached to the leadframe 22 by solder layer 31, which is in the form of solder paste. This assembly then goes through a second solder reflow process to ensure solder bonding of the respective surfaces by solder layers 31 and 48.

At this point, the entire assembly of leadframes 12, 22 and die 40 is flipped over such that leadframe 12 is on top. Patches of solder paste 83, 85 are then dispensed on leadframe 12 in the locations shown. Subsequently passive components 82, 84 are placed in engagement with solder paste patches 83, 85, respectively. Then the entire assembly goes through a third reflow process to cure the solder paste to form solder layers 83, 85 that bond the passive components 82, 84 to the first leadframe 12. The entire assembly, thus connected, now proceeds to a molding process where the assembly is encapsulated in mold compound 70.

The solder balls 60, 62, 64 undergo volume expansion and contraction during each of the three reflow processes described above. These solder ball expansion and contraction cycles can rupture the adjacent passivation layer(s) 54, etc. As a result a solder bridge 76 may be formed that extends between adjacent solder balls, e.g. 60, 62, causing a short-circuit.

FIG. 2 illustrates another problem that may occur in an integrated circuit package 10 of the same construction as shown in FIG. 1. The IC package 10 of FIG. 2 is created by the same process as described above with reference to FIG. 1. However, in FIG. 2 the heating of the first (bottom) leadframe 12 during attachment of components 82, 84 to the first leadframe has caused heat from the reflow process to be transferred to the first (bottom) leadframe 12 and through it and the connecting lead 30 to the second (top) leadframe 22. The top leadframe 22 has fewer cut outs and open spaces than the bottom leadframe and thus tends to expand more with a temperature increase than the bottom leadframe. As a result, the top leadframe 22 bends upwardly in the middle 25 in a bow shape. This upward movement of the middle of the top leadframe 22 tends to pull the attached IC die up with it, causing balls 60A, 60B, 60C to elongate. After application of the mold compound, this elongated shape with an increased distance between the two leadframes 12, 22 remains. Such a change in the dimensions and shape of the integrated circuit package 10 is undesirable.

FIG. 14 illustrates an integrated circuit package 100 in which a plurality of copper pillars 142 attach each bump pad 114, 115 of an integrated circuit die 110 to a first (lower) leadframe 160. This integrated circuit package 100 may substantially reduce the risk of the problem of solder bridging or solder ball elongation that is described above for integrated circuit package 10 shown in FIGS. 1 and 2.

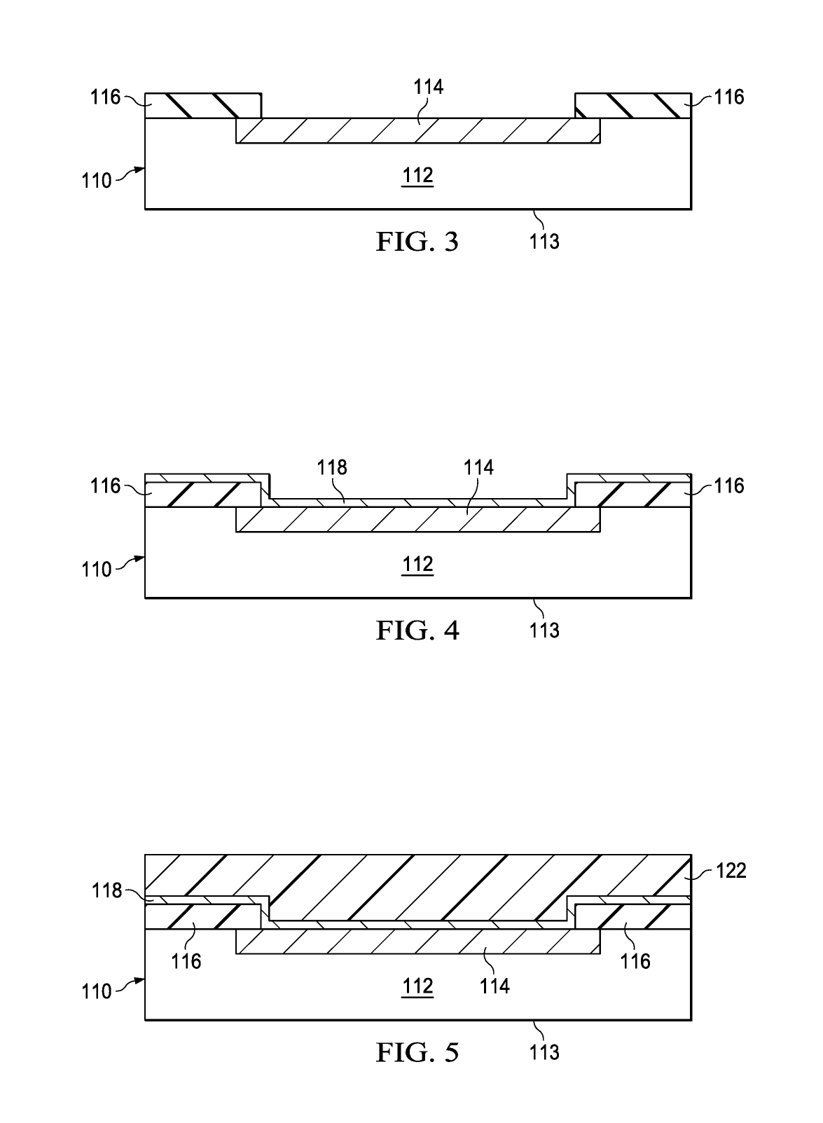

A manner in which such an integrated circuit package 100 may be made will now be described with reference to FIGS. 3-14. In general, the sequence of steps for forming the IC package 100 with a first and second leadframe 160, 170; IC die 140 and electronic components 190 may be generally the same as described above with reference to FIG. 1, except for the formation and use of compound copper and intermetallic columns instead of solder balls.

A conventional integrated circuit die 110, such as illustrated in FIG. 3, may be produced in a manner known in the art. In FIG. 3 only a portion of the die 110 and a single bump pad 114 thereof is shown, but it will be understood that typically multiple bump pads are present on the die 110. In a typical process, the entire wafer from which the die 110 is ultimately singulated will be operated on at each of the steps illustrated FIGS. 3-10. Thus, it is to be understood that the die portions shown in FIGS. 3-10 also illustrate portions of an entire wafer prior to singulation thereof.

Integrated circuit 110, FIG. 3, may include a silicon block 112 with conventional integrated circuitry therein. A bump pad 114 provides a means for connecting the circuitry in the silicon block 112 to external circuitry. The bump pad 114 is constructed from conductive material, such as metal, and is circumscribed by a passivation layer 116, as is known in the art.

As illustrated by FIG. 4, a seed layer 118, which may be titanium-copper (“Ti/Cu”) is applied to the passivation layer 116 and bump pad 114, as by sputtering. Next, as illustrated by FIG. 5, a layer of photoresist material 122 is applied across the entire wafer, as by a spin coating process. The wafer is then soft baked.

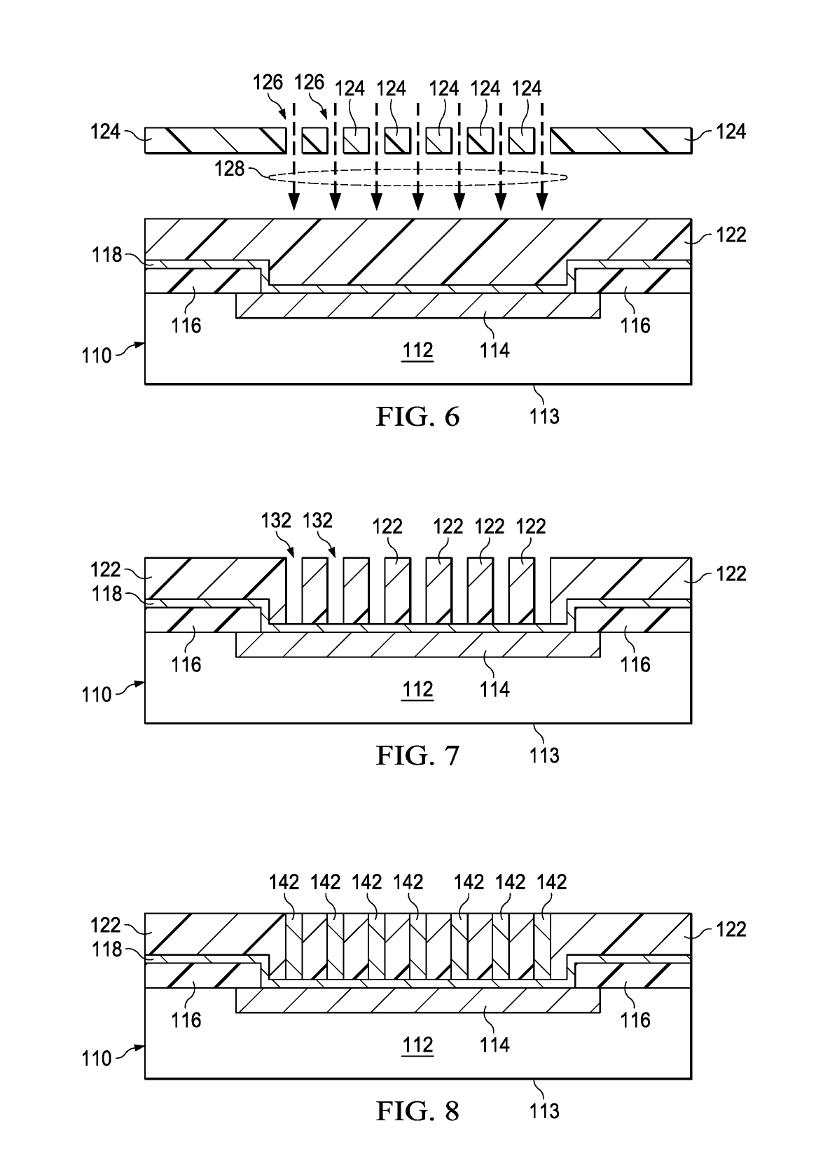

Next, as illustrated in FIG. 6, a photolithography process is performed, during which ultraviolet light 128 is passed through holes 126 in a mask 124 onto the layer of photoresist material 122. The size and spacing of the holes 126 in the mask 124 determine the size and spacing of copper pillars 142 that are subsequently formed.

The photoresist layer 122 is then conventionally developed to produce openings 132 in layer 122, as shown by FIG. 7. Next, as shown in FIG. 8, during a conventional copper plating process, copper is plated into the openings 132 to produce a plurality of copper pillars 142 that are surrounded by photoresist material 122.

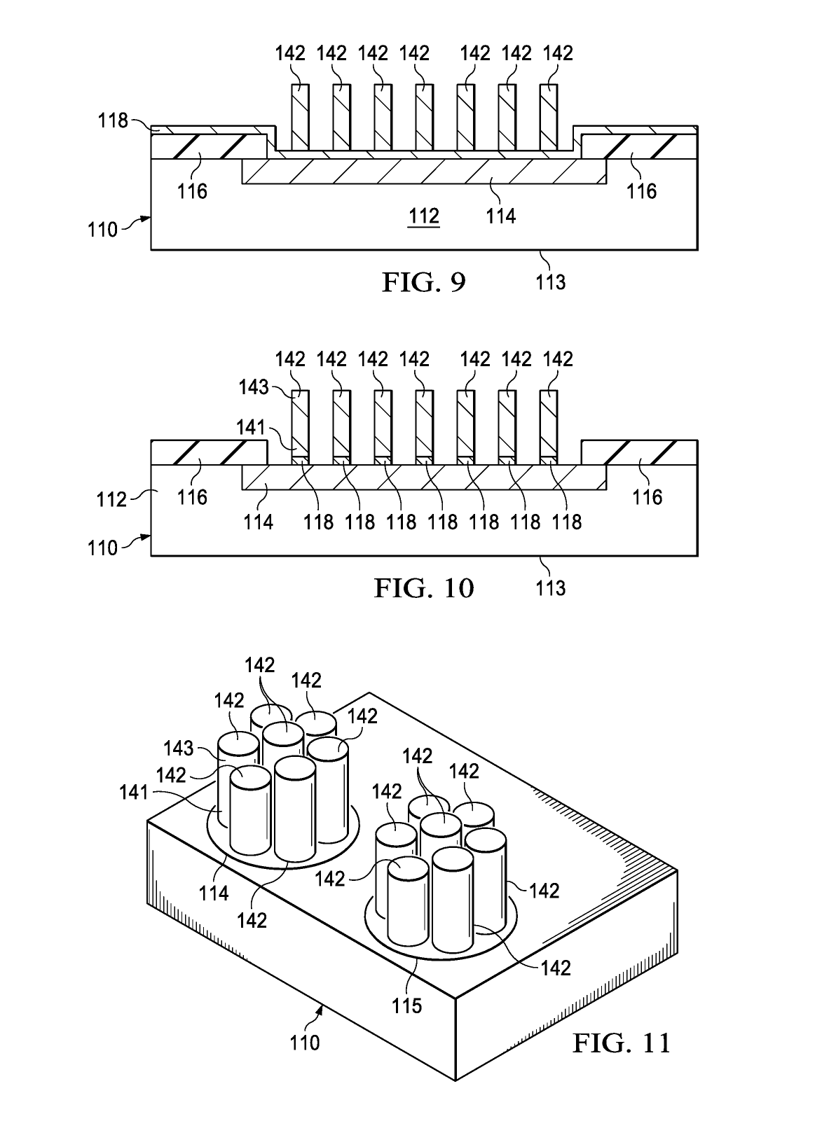

Next, the remaining photoresist of layer 122 is conventionally stripped away, leaving copper pillars 142 extending upwardly from the seed layer 118, FIG. 9. Each pillar 142 has a first (proximal) end 141 attached to the bump pad 114 and a second (distal) end 143 that is free.

Next, as shown by FIG. 10, the seed layer 118 is etched away, leaving only the copper pillars 142 (and the portions of the seed layer 118 positioned immediately below the pillars) on the bump pad 114.

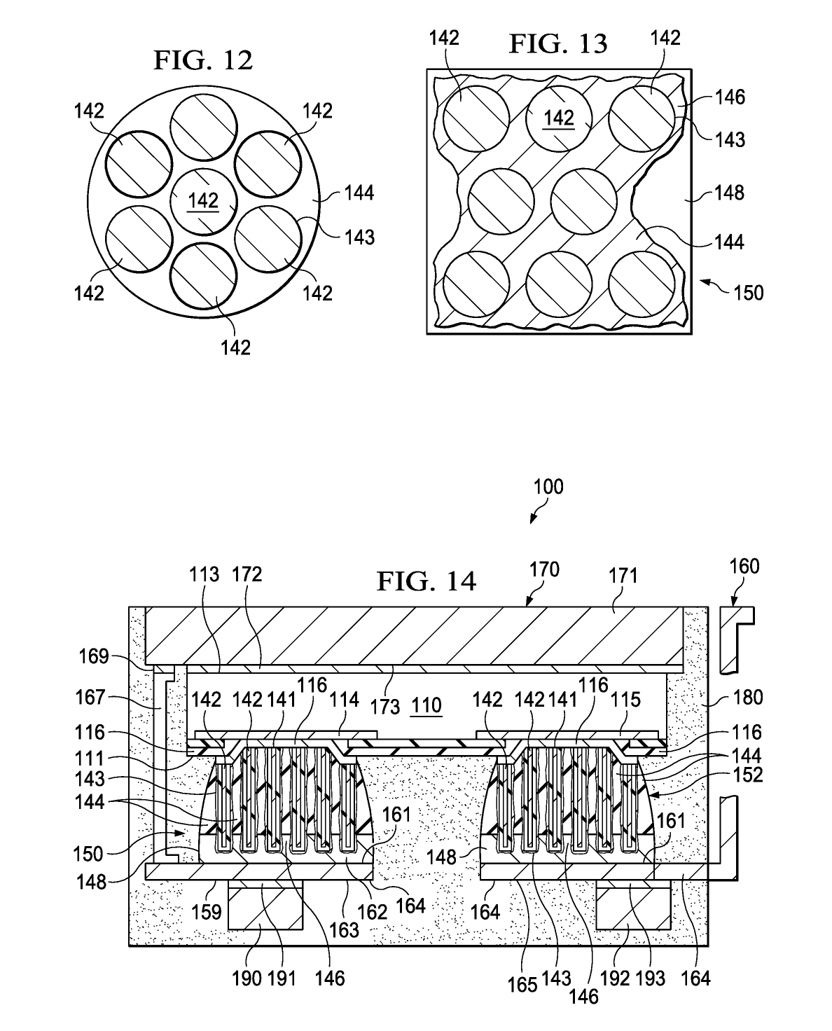

The pillar configuration produced by the process of FIG. 10 is shown on adjacent bump pads 114, 115 in FIG. 11. As shown by FIG. 12, which is a view of one of the sets of pillars 142 of FIG. 11 looking toward of the die 110, the copper pillars 142 are separated by small gaps or spaces 144. FIG. 13 is a view from the same perspective as FIG. 12, but showing another embodiment of the pillars 142, in which there are more pillars provided on the die pad 114, and in a slightly different arrangement. As shown by FIG. 13, the spaces 144 are filled with intermetallic compound 146 around a portion of each pillar that is proximate to the die 110, and by solder 148 around the end 143 of each pillar that is remote from the die.

The process by which the space 144 between pillars 142 is filled takes place when the IC die 110, with the copper pillars 142 attached to its respective bump pads 114, 115, is attached to the first leadframe 160.

This process by which the die 110 is attached to the first leadframe 160 will now be described with reference to FIG. 14. Solder paste 148, which may be particle type 5/6, is deposited on the first (bottom) leadframe 160 on the top surface 161 of the leads/contacts 163, 165 where each set of copper pillars 142 is to be attached. The die 110 and attached copper pillars 142 are then positioned such that the free ends 143 of the copper pillars 142 engage the layer of solder paste 163. Then the die 110, attached copper pillars 142 and the first leadframe 160 undergo a reflow heating process.

During reflow the solder paste 148 melts and flows into the spaces 144 between copper pillars 142. At the same time, the reflowed solder 148 reacts with the copper in the copper pillars 142 to form intermetallic compounds Cu₃Sn and Cu₆Sn₅. An intermetallic layer 146 thus formed encompasses a length of each copper pillar 142 that is located nearer the die 110. The remainder of the solder layer 148 encompasses the end portion 143 of each pillar that is located near the first leadframe 160.

The intermetallic layer 146 has a high melting temperature and therefore does not re-melt and solidify during any subsequent reflow cycles (such as those performed during attachment of the IC die 110 to the die attach pad 171 of the second leadframe 170 or the attachment of electronic components 190, 192 to the first leadframe 160, described below). The intermetallic layer 146 is not brittle and is not easily broken and therefor does not damage interfacing layers such as passivation layer 116. The columns thus formed from a plurality of copper pillars, intermetallic compound 146 and solder 148 are referred to herein as compound columns 150, 152.

After attaching the die 110 to the first leadframe 160 the second leadframe is attached to the die 110 and the first leadframe 160. To begin with, the unattached second leadframe 170 is flipped over relative to the orientation shown in FIG. 14, such that bottom surface 173 is up. Solder paste patches 169 and 172 are then applied to upward facing surface 173 of second leadframe 170. The die 110 and first leadframe 160 assembly is also flipped over and the die backside surface 113 is placed in engagement with the patch of solder paste 172. At the same time, an end surface of a connector lead 167 of first leadframe 160 is placed in engagement with the solder paste patch 169. The first leadframe 160, second leadframe 170 and die 110 assembly is then heated in a second reflow process that cures the solder paste patches 169, 172. Thus solder layer 169 is formed bonding leadframe connector lead 167 to the second leadframe 170. At the same time solder layer 172 is formed bonding the IC die 110 to the second leadframe 170.

Next the passive components 190, 192 are attached to the assembly. The assembly 169/172/110 is oriented with the bottom surface 164 of the first leadframe 160 facing up. Patches of solder paste 191, 193 are applied to the first leadframe surface 160 in the areas shown in FIG. 14. Electronic components 192, 194 are then positioned in engagement with the patches of solder paste 191, 193 and the entire assembly is heated in a third reflow process, reflowing the solder paste to form solder bonds 191, 193 between the passive electronic components 190, 192 and to the first leadframe 160.

Next, a layer of mold compound 180 is applied. The mold compound 180 covers at least portions of the two substrates/leadframes 160, 170; the integrated circuit die 110; the two compound columns 150, 152; and the electronic components 190, 192.

The behavior of the compound columns 150, 152 during reflow periods subsequent to the formation of columns 150, 152 will now be described. The distal end 143 of each copper pillar 142 is enclosed in solder 148, which does melt and solidify during subsequent reflow cycles. However, the volume of the solder layer 148 is very low compared to the volume of the intermetallic layer 146. The expansion and contraction in this solder layer 148, because of its low volume, is not nearly as pronounced as that of the solder balls 62, etc., in the integrated circuit packages 10 described above. As a result there is not significant stress placed on any interfaces of the integrated circuit package 110. Also, the columns formed by the copper pillars 142 and the intermetallic layer 146, which do not melt during subsequent reflow processes do not significantly elongate under the stress associated with buckling of the top leadframe 170, and not nearly as much as the solder balls 60A, etc., described with reference to FIG. 2. The risk of solder bridging or elongation of the IC package as described above with reference to FIGS. 1 and 2 is substantially reduced or eliminated.

The integrated circuit package 100 illustrated in FIG. 14 thus has an integrated circuit die 110 sandwiched between a first (bottom) leadframe 160 and a second (top) leadframe 170. The proximal ends 141 of copper pillars 142 are attached to die bump pads 114, 115. Solder layer 148 on the top surface 161 of the bottom leadframe contacts 163, 165 attaches the distal ends 143 of the copper pillars to the contacts 163, 165. The portion of each pillar 142 positioned between the solder layer 148 and the integrated circuit die bump pads 114, 115 is encompassed by intermetallic compound 146.

A portion of the backside (top) 113 of the die 110 is attached, by a layer of solder 172, to a bottom surface 173 of the top leadframe 170. Another portion of the backside (top) 113 of the die is attached to connector lead 167 of the first leadframe 160 by solder layer 169. The bottom leadframe 160 may have passive components 190, 192 mounted on a bottom surface 164 thereof by solder layers 191, 193. The top and bottom leadframes 160, 170, the die 110, the compound columns 150, 152, and the components 192, 194 may all be covered entirely or partially with mold compound 180.

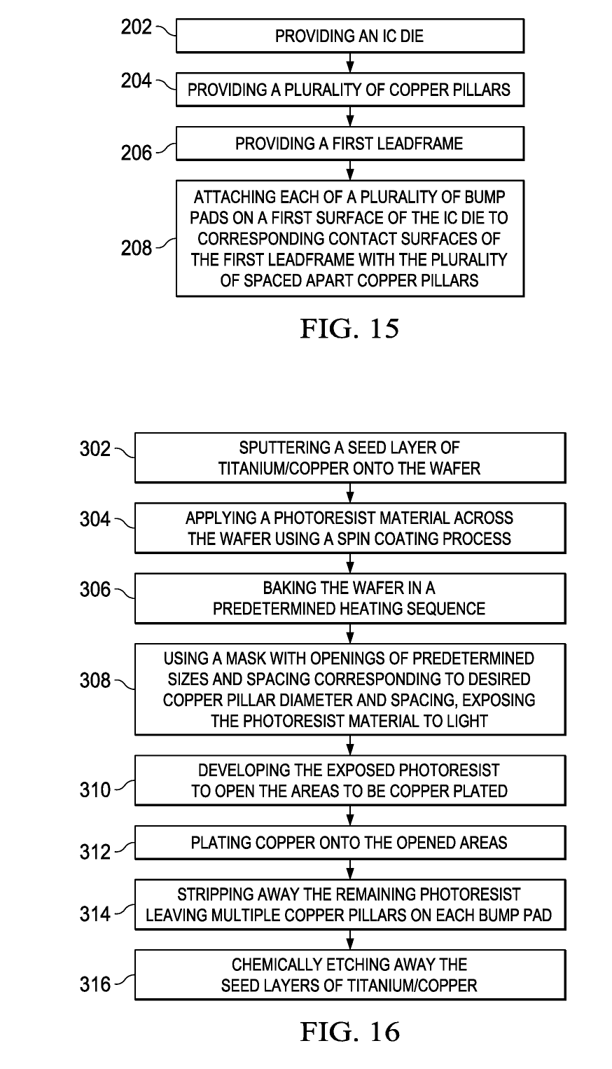

It will be appreciated from the above that a method of making an integrated circuit (“IC”) package has been described as set forth in FIG. 15. The method may include, as shown at block 202, providing an IC die and, as shown at block 204, providing a plurality of copper pillars. The method may further include, as shown at block 206, providing a first leadframe and, as shown at block 208, attaching each of a plurality of bump pads on a first surface of the IC die to corresponding contact surfaces of the first leadframe with the plurality of spaced apart copper pillars.

It will also be appreciated that a method of forming a plurality of copper pillars on bump pads of an IC wafer has been described as set forth in FIG. 16. The method may include, as shown at 302, sputtering a seed layer of titanium/copper onto the wafer and, as shown at 304, applying photoresist material across the wafer using a spin coating process. The method may further include, as shown at 306, baking the wafer in a predetermined heating sequence and, as shown at 308, using a mask with openings of predetermined sizes and spacing corresponding to desired copper pillar diameter and spacing and, as shown at 308, exposing the photoresist material to light. The method may still further include, as shown at 310, developing the exposed photoresist to open the areas to be copper plated and, as shown at 312, plating copper onto the opened areas. The method may also include, as shown at 314, stripping away the remaining photoresist leaving multiple copper pillars on each bump pad and, as shown at 316, chemically etching away the seed layers of titanium/copper.

As used herein terms such as top, bottom, upper, lower, vertical, horizontal, lateral and the like are used in a relative sense to describe the spacial relationship between different objects or parts of an object, i.e., such terms are not used in an absolute sense referring to a particular orientation of an object in a gravitational field. Thus, as used in this sense, the roof of the car, once described as the “top” of the car, would still accurately be referred to as the “top” of the car, even if the car were inverted or on its side.

Although certain specific embodiments of an integrated circuit package have been described in detail, it will be clear to those skilled in the art that the inventive concepts disclosed herein may be otherwise embodied. The claims appended hereto are intended to be broadly construed to cover such alternative embodiments, except to the extent limited by the prior art.

What is claimed is:

1. An integrated circuit (IC) package comprising:
an IC die having a first side and a second side opposite the first side;
a bump pad on the first side;
a first substrate having a first side with a plurality of electrical contact surfaces;
a plurality of metal pillars, each having a first end attached to the bump pad via a passivation layer, and a second end attached to one of a plurality of electrical contact surfaces of a first substrate;
an intermetallic compound surrounding portions of the plurality of metal pillars; and
a mold compound encapsulating the intermetallic compound.

2. The IC package of claim 1, wherein the plurality of metal pillars include copper.

3. The IC package of claim 1, wherein the intermetallic compound comprises a copper and lead compound.

4. The IC package of claim 3, wherein the copper and lead compound comprises Cu₃Sn.

5. The IC package of claim 3, wherein the copper and lead compound comprises Cu₆Sn₅.

6. The IC package of claim 1 further comprising a second substrate attached to the second side of the IC die.

7. The IC package of claim 6, wherein the mold compound encapsulates at least a portion of the IC die, and the first and second substrates.

8. The IC package of claim 6, wherein said first substrate comprises a first leadframe and wherein said second substrate comprises a second leadframe.

9. The IC package of claim 1, wherein the intermetallic compound has higher melting temperatures than solder and lower coefficients of expansion than solder.

10. An integrated circuit (“IC”) package comprising:
an IC die having a first side and a second side opposite the first side;
a bump pad on the first side;
a first substrate having a first side with a plurality of electrical contact surfaces;
a plurality of metal pillars, each having a first end attached to the bump pad via a passivation layer, and a second end attached to one of a plurality of electrical contact surfaces of a first substrate;
an intermetallic compound surrounding a first portion of the plurality of metal pillars;
a solder layer surrounding a second portion of the plurality of metal pillars;
a mold compound surrounding the intermetallic compound and the solder layer.

11. The IC package of claim 10, wherein the first portion is proximate the IC die.

12. The IC package of claim 10, wherein the second portion is proximate the first substrate.

13. The IC package of claim 10, wherein the intermetallic compound comprises a copper and lead compound.

14. The IC package of claim 13, wherein the copper and lead compound comprises Cu₃Sn.

15. The IC package of claim 13, wherein the copper and lead compound comprises Cu₆Sn₅.
